(19) United States
(12) Patent Application Publication
(10) Pub. No.: US 2013/0327924 A1
(43) Pub. Date: Dec. 12, 2013

(54) SOLID-STATE IMAGE SENSOR, CONTROL METHOD FOR THE SAME, AND ELECTRONIC DEVICE

(71) Applicant: Sony Corporation, Tokyo (JP)

(72) Inventor: Takashi Machida, Tokyo (JP)

(73) Assignee: Sony Corporation, Tokyo (JP)

(21) Appl. No.: 13/904,280

(22) Filed: May 29, 2013

(30) Foreign Application Priority Data
Jun. 6, 2012 (JP) 2012128539

(51) Int. Cl. H01L 27/148

(52) U.S. Cl. CPC H01L 27/14812
USPC 250/208.1; 257/229

(57) ABSTRACT

There is provided a solid-state image sensor including unit pixels each including a photoelectric transducer which generates a charge corresponding to an amount of incident light and accumulates the charge therein, a first transfer gate which transfers the charge accumulated in the photoelectric transducer, a charge holding region in which the charge transferred from the photoelectric transducer by the first transfer gate is held, a second transfer gate which transfers the charge held in the charge holding region, a floating diffusion region in which the charge transferred from the charge holding region by the second transfer gate is held to be read out as a signal, and a reset section which resets the charge in the floating diffusion region. The first transfer gate and the reset section are connected to an identical drive section through a drive line shared thereby, and are simultaneously driven by the drive section.

### BACKGROUND

The present disclosure relates to a solid-state image sensor, a control method for the same, and an electronic device, and particularly relates to a solid-state image sensor, a control method for the same, and an electronic device which make it possible to restrain increase of the number of wirings in a pixel structure having a memory part.

As a solid-state image sensor, there is provided, for example, a CMOS (Complementary Metal Oxide Semiconductor) image sensor which reads out, through MOS transistors, optical charges (charges) accumulated in PN junction capacitors in photo diodes which are photoelectric transducers.

The CMOS image sensor executes operation of reading out the charges accumulated in the photo diodes on a pixel basis, on a row basis, or the like. Accordingly, it is not possible to provide all the pixels with the same exposure time period during which the charges are accumulated, and thus distortion occurs in an image taken at timing when a subject is moving or the like.

FIG. 1 illustrates a configuration example of one of unit pixels.

As illustrated in FIG. 1, each of unit pixels 20A includes a photodiode (PD) 21, a transfer gate 24, a floating diffusion 25, a reset transistor 26, an amplification transistor 27, and a select transistor 28.

In the unit pixel 20A, the photo diode 21 is a buried photodiode formed, for example, by forming a P-type layer 33 in a front surface of a P-type well layer 32 formed on an N-type substrate 31 and by burying an N-type buried layer 34 in the P-type well layer 32. The P-type well layer 32 is formed below the transfer gate 24. When the transfer gate 24 is in an off state, a potential barrier prevents a charge from moving. On the other hand, when the transfer gate 24 is in an on state, the potential barrier below the transfer gate 24 is lowered, a charge accumulated in a pn junction in the photo diode 21 is transferred to the floating diffusion 25, and voltage change therefrom is outputted to a signal line 17 through the amplification transistor 27.

(Mechanical Shutter Method)

A mechanical shutter method using a mechanical light shielding unit is widely used as one of methods by which global exposure is implemented for a solid-state image sensor including the unit pixel 20A having the aforementioned configuration. In the global exposure, an image is captured with all the pixels having the same exposure time period. The global exposure is executed in such a manner that all the pixels simultaneously start exposure and simultaneously terminate the exposure.

In the mechanical shutter method, the exposure time is mechanically controlled to thereby provide each pixel with the same time period in which a charge is generated when light enters the photo diode 21. Then, the mechanical shutter is closed, and the state changes to a state where no charge is substantially accumulated. In this state, signals are read out sequentially. However, the necessity of providing the mechanical light shielding unit makes downsizing difficult, and the speed at which the mechanism is driven is limited. For this reason, the mechanical shutter method is inferior to an electrical method in concurrency.

(Global Exposure in Related Art)

Here, with reference to FIGS. 2 and 3, a description is given of operation for achieving image capturing in the unit pixel 20A in FIG. 1 without distortion by providing all the pixels with the same exposure time period.

FIG. 2 illustrates a timing chart of a selection pulse SEL, a transfer pulse TRG, and a reset pulse RST, in a one-frame time period, of each of the unit pixels 20A in the i-th and (i+1)-th rows in a pixel array section, the unit pixels 20A being two-dimensionally arranged in a matrix form in the pixel array section.

FIG. 3 illustrates potential diagrams of the unit pixel 20A at times t1 to t6 in FIG. 2. Note that in each potential diagram, a potential is indicated in a vertical direction, and the potential becomes lower in an upward direction. Squares shown below characters of TRG and RST in the figure indicate states of the transfer pulse TRG and the reset pulse RST. Specifically, a black square indicates that the corresponding pulse is on, and an outlined square indicates that the pulse is off.

In FIG. 2, a time period from time t1 to time t3 is an accumulation time period in which a charge corresponding to an amount of incident light is accumulated simultaneously in each pixel.

Specifically, at time t1, a transfer pulse TRG and a reset pulse RST are turned on in each pixel simultaneously, and charges in the photo diode 21 and the floating diffusion 25 are discharged. Thereafter, the transfer pulse TRG and the reset pulse RST are turned off, and exposure is started simultaneously in each pixel. A charge corresponding to the amount of incident light is accumulated in the photo diode 21, as illustrated at time t2.

At time t3, the transfer pulse TRG is turned on in each pixel simultaneously, the charge accumulated in the charge accumulated in the photo diode 21 is transferred to the floating diffusion 25, and then the transfer pulse TRG is turned off. Thereby, the charge accumulated in the same exposure time period in each pixel is held in the floating diffusion 25.

Thereafter, the accumulated charges are read serially in row unit in a readout time period for the i-th and (i+1)-th rows.

Specifically, a pixel signal is read out at time t4, the pixel signal indicating a voltage based on the charge accumulated in the floating diffusion 25 (hereinafter, referred to as a signal level). At time t5, the floating diffusion 25 is reset. Hereinafter, a readout time period for the signal level is referred to as a D period.

At time t6, a signal is read out, the signal indicating a voltage of the floating diffusion 25 from which the charge has been discharged (hereinafter, referred to as a reset level). Hereinafter, a readout time period for the reset level is referred to as a P period.

As described above, when the signal indicating the signal reset level is read out, noise of the signal level is removed by using the reset level in signal processing in the subsequent stage. In the signal removing processing, the reset level is read out which results from reset operation executed after the signal level is read out. Accordingly, it is not possible to remove kTC noise (thermal noise) in the reset operation, and thus the image quality is deteriorated.

The kTC noise in the reset operation is random noise generated due to reset transistor switching operation in the reset operation. Accordingly, if a level before transferring the charge to the floating diffusion 25 is not used, it is not possible to appropriately remove the noise of the signal level. Since the charge is transferred to the floating diffusion 25 simultaneously in each pixel, and thus the noise is removed at this time in such a manner that the signal level is read out and thereafter the reset operation is executed again. Accordingly, it is possible to remove noise such as an offset error, but not possible to remove the kTC noise.

Meanwhile, it is known that many crystalline defects at a Si—SiO2 interface are likely to cause a dark current. In the case where charges are held in the floating diffusions 25, dark currents to be applied to the signal levels differ from each other depending on the order of reading out the charges. The noise removal based on the reset level does not enable this to be cancelled, either.

Such a solid-state image sensor is proposed in JP H01-243675A and JP 2004-140149A, for example.

(Pixel Structure Having Memory Part)

As a structure enabling the kTC noise removal, a structure is proposed in which unit pixels are each provided with a charge holding region besides a floating diffusion as illustrated in FIG. 4.

As illustrated in FIG. 4, each of unit pixels 20B is provided with a memory part (MEM) 23 besides a floating diffusion (FD) 25. The memory part 23 temporarily holds a charge accumulated in the photo diode (PD) 21. The unit pixel 20B is further provided with a first transfer gate 22 which transfers the charge accumulated in the photo diode (PD) 21 to the memory part 23.

In the unit pixel 20B including the memory part 23, the charge accumulated in the photo diode (PD) 21 is once transferred to the memory part 23, thereafter the charge is serially transferred to the floating diffusion (FD) 25 to perform readout operation.

Here, operation of executing the global exposure in the unit pixel 20B including the memory part 23 will be described with reference to FIG. 5. FIG. 5 illustrates potential diagrams of the unit pixel 20B at times t1 to t7. Squares shown below characters of TRX, TRG, and RST in the figure indicate states of a transfer pulse TRX, a transfer pulse TRG, and a reset pulse RST.

A time period from time t1 to time t3 is an accumulation time period in which a charge corresponding to an amount of incident light is accumulated simultaneously in each pixel.

Specifically, at time t1, a transfer pulse TRX, a transfer pulse TRG, and a reset pulse RST are turned on in each pixel simultaneously, and charges in the photo diode 21, the memory part 23, and the floating diffusion 25 are discharged. Thereafter, the transfer pulse TRX, the transfer pulse TRG, and the reset pulse RST are turned off, and exposure is started simultaneously in each pixel. A charge corresponding to the amount of incident light is accumulated in the photo diode 21, as illustrated at time t2.

At time t3, the transfer pulse TRX is turned on in each pixel simultaneously, the charge accumulated in the photo diode 21 is transferred to the memory part 23, and then the transfer pulse TRX is turned off.

A time period from time t4 to time t7 is a readout time period in which the accumulated charges are read out sequentially in row unit.

Specifically, at time t4, the reset pulse RST is turned on, the floating diffusion 25 is reset, the charge is discharged from the floating diffusion 25, and then the reset pulse RST is turned off.

At time t5, a pixel signal indicating the reset level is read out. At time t6, the transfer pulse TRG is turned on, the charge accumulated in the memory part 23 is transferred to the floating diffusion 25, and then the transfer pulse TRG is turned off.

At time t7, a pixel signal indicating the signal level is read out. At this time, reset noise included in the signal level coincides with reset noise read out in reading out the reset level. This enables processing of reducing noise including even the kTC noise.

As is clear from this, according to the pixel structure in which a memory part temporarily holding a charge accumulated in a photo diode is provided besides a floating diffusion region, it is possible to achieve processing of reducing noise including even kTC noise.

Such a solid-state image sensor is proposed in JP 2006-311515A and JP H11-177076A, for example.

### SUMMARY

Meanwhile, a solid-state image sensor in a pixel structure having a memory part has a larger number of transistors forming unit pixels than a solid-state image sensor in related art does, and thus has a larger number of drive lines for driving the transistors.

The larger number of drive lines might have the following risks. Specifically, a smaller region for making light incident on the photo diode might cause sensitivity deterioration, and increase of wiring short-circuit or opening probability might cause yield deterioration. For this reason, it is preferable that the number of wirings be as small as possible.

The present technology has been provided under such circumstances and makes it possible to restrain increase of the number of wirings in a pixel structure having a memory part.

According to a first embodiment of the present technology, there is provided a solid-state image sensor including a plurality of unit pixels each including a photoelectric transducer which generates a charge corresponding to an amount of incident light and accumulates the charge therein, a first transfer gate which transfers the charge accumulated in the photoelectric transducer, a charge holding region in which the charge transferred from the photoelectric transducer by the first transfer gate is held, a second transfer gate which transfers the charge held in the charge holding region, a floating diffusion region in which the charge transferred from the charge holding region by the second transfer gate is held to be read out as a signal, and a reset section which resets the charge in the floating diffusion region. The first transfer gate and the reset section are connected to an identical drive section through a drive line shared by the first transfer gate and the reset section, and are simultaneously driven by the drive section.

The first transfer gate may partially or entirely cover the charge holding region.

The drive section may set a first voltage in driving the reset section to be lower than a second voltage in driving the first transfer gate.

According to the first aspect of the present technology, there is provided a control method for the aforementioned solid-state image sensor according to the first aspect of the present technology.

In the solid-state image sensor and the control method according to the first aspect of the present technology, the first transfer gate and the reset section are connected to the drive section through the drive line shared by the first transfer gate and the reset section, and are simultaneously driven by the drive section.

According to a second embodiment of the present technology, there is provided an electronic device having a solid-state image sensor mounted thereon, the solid-state image sensor including a plurality of unit pixels each including a photoelectric transducer which generates a charge corresponding to an amount of incident light and accumulates the charge therein, a first transfer gate which transfers the charge accumulated in the photoelectric transducer, a charge holding region in which the charge transferred from the photoelectric transducer by the first transfer gate is held, a second transfer gate which transfers the charge held in the charge holding region, a floating diffusion region in which the charge transferred from the charge holding region by the second transfer gate is held to be read out as a signal, and a reset section which resets the charge in the floating diffusion region. The first transfer gate and the reset section are connected to an identical drive section through a drive line shared by the first transfer gate and the reset section, and are simultaneously driven by the drive section.

In the electronic device according to the second aspect of the present technology, the first transfer gate and the reset section are connected to the drive section through the drive line shared by the first transfer gate and the reset section, and are simultaneously driven by the drive section.

According to the first and second aspects of the present technology, it is possible to restrain increase of the number of wirings in a pixel structure having a memory part.

### BRIEF DESCRIPTION OF THE DRAWINGS

FIG. 1 is a cross-sectional diagram illustrating a configuration example of one of unit pixels in related art;

FIG. 2 is a timing chart illustrating a method for driving the unit pixels in the related art.

FIG. 3 is a potential diagram illustrating the method for driving the unit pixels in the related art;

FIG. 4 is a cross-sectional diagram illustrating a configuration example of one of unit pixels in related art;

FIG. 5 is a potential diagram illustrating a method for driving the unit pixels in the related art;

FIG. 6 is a diagram illustrating a configuration example of a CMOS image sensor;

FIG. 7 illustrates plan diagrams of a configuration example of one of unit pixels;

FIG. 8 is a cross-sectional diagram illustrating a configuration example of the unit pixel;

FIG. 9 is a timing chart illustrating a method for driving the unit pixels.

FIG. 10 is a potential diagram at time t1;

FIG. 11 is a potential diagram at time t2;

FIG. 12 is a potential diagram at time t2;

FIG. 13 is a potential diagram at time t3;

FIG. 14 is a potential diagram at time t4;

FIG. 15 is a potential diagram at time t5;

FIG. 16 is a potential diagram at time t6;

FIG. 17 is a potential diagram at time t7;

FIG. 18 is a potential diagram at time t8;

FIG. 19 is a potential diagram at time t9;

FIG. 20 is a potential diagram at time t10;

FIG. 21 is a potential diagram at time t11;

FIG. 22 is a diagram illustrating another configuration example of the CMOS image sensor;

FIG. 23 is a diagram illustrating still another configuration example of the CMOS image sensor; and

FIG. 24 is a diagram illustrating a configuration example of an imaging apparatus.

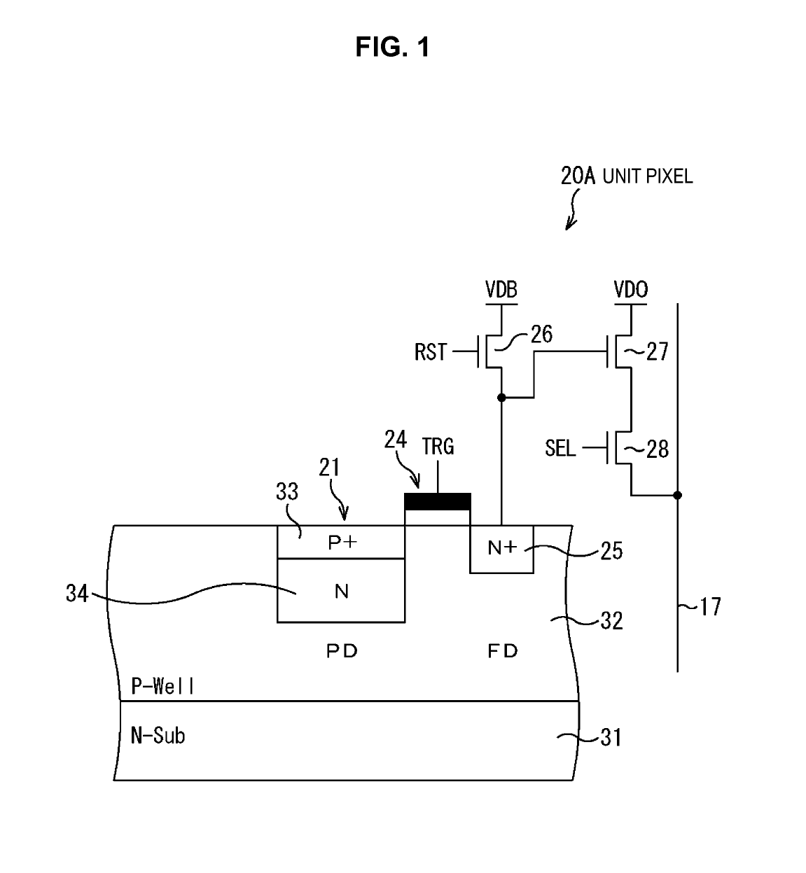

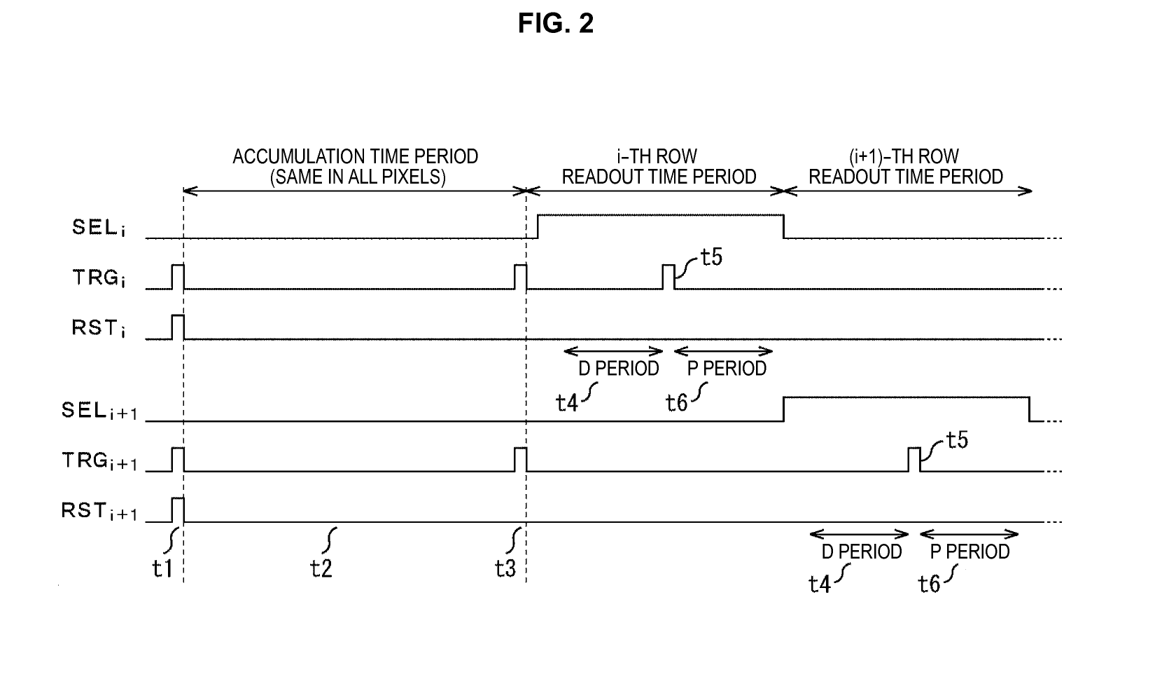

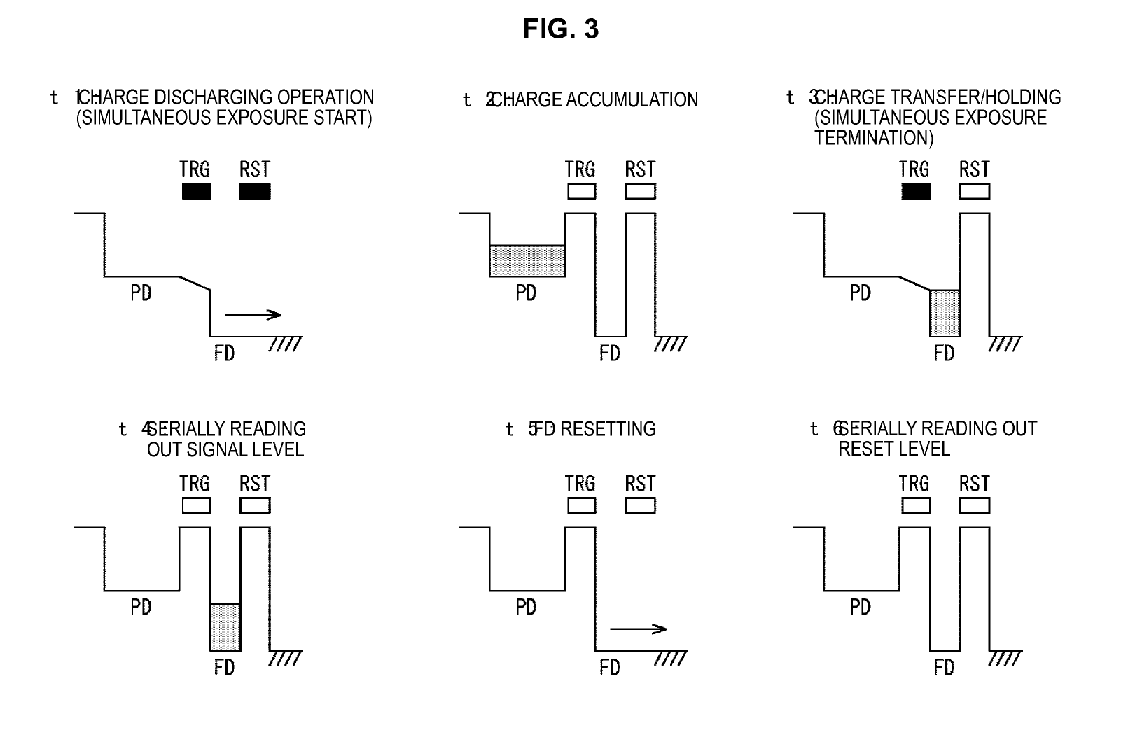

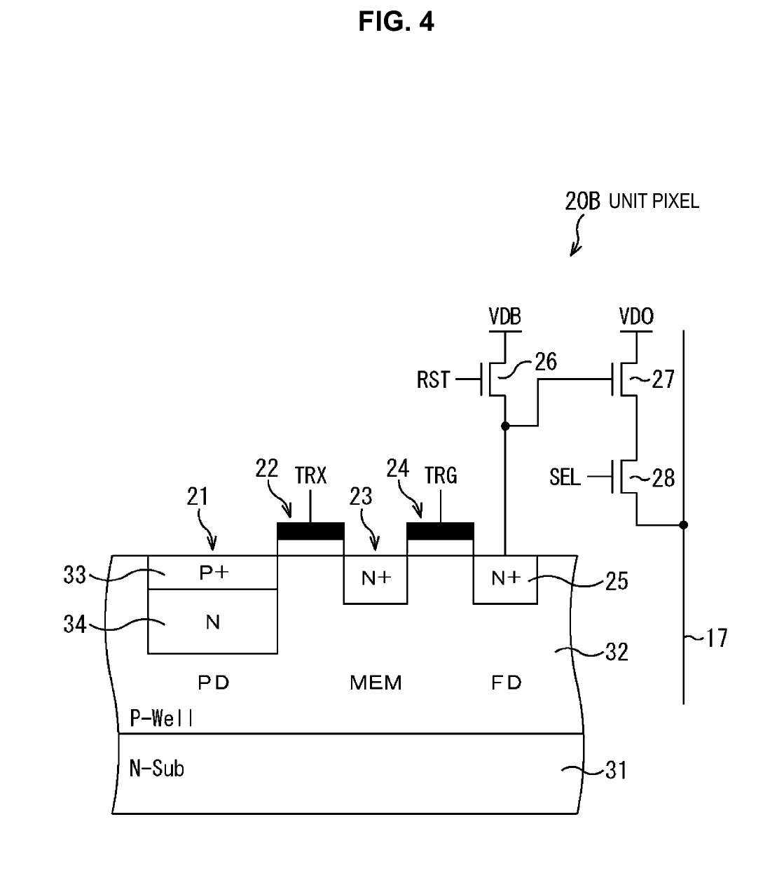

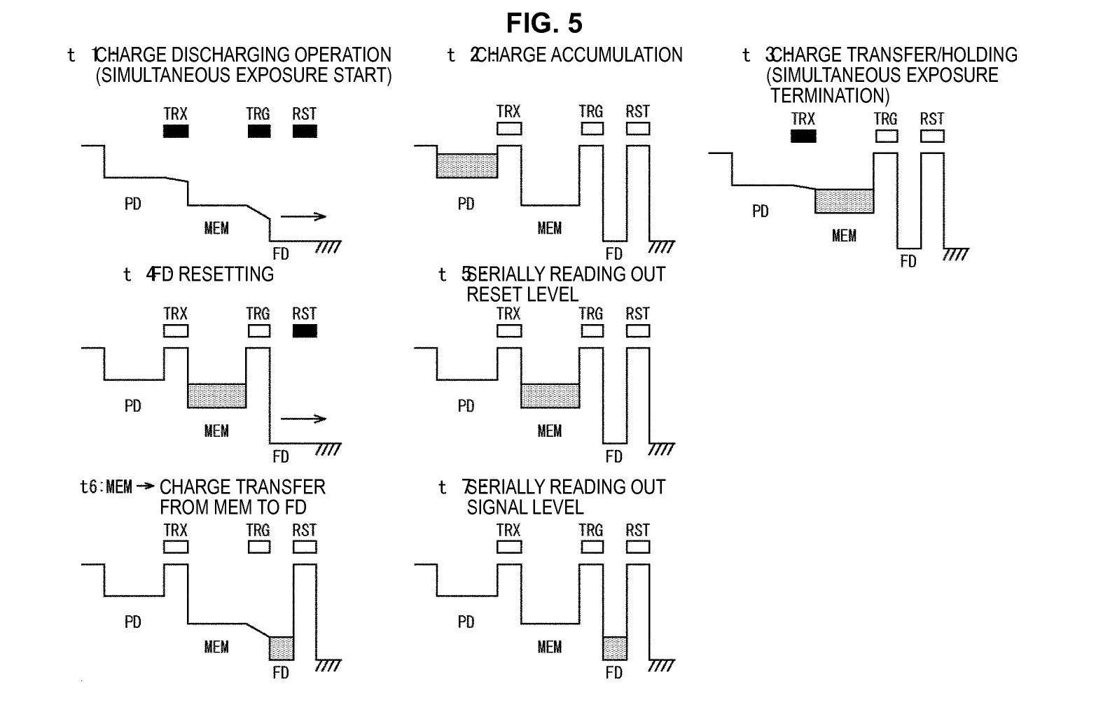

### DETAILED DESCRIPTION OF THE EMBODIMENT

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

[Configuration Example of Solid-State Imaging Apparatus]

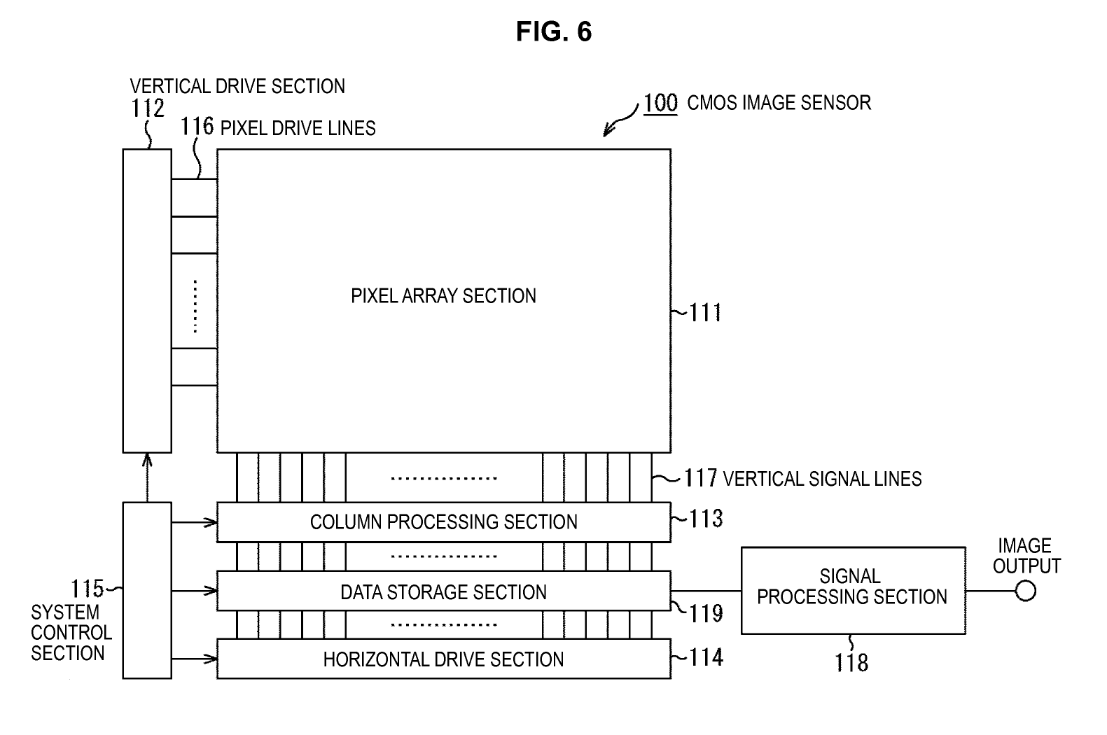

FIG. 6 is a block diagram illustrating a configuration example of a CMOS image sensor which is a solid-state imaging apparatus to which an embodiment of the present technology is applied.

As illustrated in FIG. 6, a CMOS image sensor 100 according to the present embodiment has a configuration including a pixel array section 111 which is formed on a not-shown semiconductor substrate (chip), and peripheral circuits which are integrated on the same semiconductor substrate on which the relevant pixel array section 111 is formed. The peripheral circuits include a vertical drive section 112, a column processing section 113, a horizontal drive section 114 and a system control section 115, for example.

The CMOS image sensor 100 further includes a signal processing section 118 and a data storage section 119. The signal processing section 118 and the data storage section 119 may be configured of external signal processing sections such, for example, as DSPs (Digital Signal Processors), or the like, or may be mounted on the same substrate on which the CMOS image sensor 100 is formed.

In the pixel array section 111, unit pixels (hereinafter, sometimes referred to simply as “pixels”) each having a photoelectric transducer generating charge in a charge amount corresponding to an amount of incident light to accumulate it therein are two-dimensionally arranged in a matrix form. The configuration of the unit pixel will be described later.

In the pixel array section 111, pixel drive lines 116 are formed in the horizontal direction in the figure (arrangement direction of pixels in pixel row) for each row with respect to the pixel arrays arranged in a matrix form, and vertical signal lines 117 are formed in the vertical direction (arrangement direction of pixels in pixel column) in the figure for each column. In FIG. 6, each pixel drive line 116 is indicated as one line, whereas it is not limited to one in reality. One end of the pixel drive line 116 is connected to an output terminal corresponding to each row of the vertical drive section 112.

The vertical drive section 112 is configured of a shift register, an address decoder and the like, and is a pixel drive section driving the individual pixels of the pixel array section 111 simultaneously for all pixels, or in row unit, or the like. This vertical drive section 112, the specific configuration of which is omitted in the figure, typically includes two scanning systems of a readout scanning system and a sweep scanning system.

To read signals from the unit pixels of the pixel array section 111, the readout scanning system performs selective scanning on the unit pixels serially in row unit. The sweep scanning system performs sweep scanning on a read-out row to be subjected to readout scanning by the readout scanning system. The sweep scanning precedes the readout scanning by a time equivalent to a shutter speed.

By sweep scanning due to the sweep scanning system, unrequired charges are swept out of the photoelectric transducers of the unit pixels in the read-out row (are reset). By this sweeping-out (resetting) of the unrequired charges due to the sweep scanning system, so-called electronic shutter operation is performed. Herein, the electronic shutter operation is an operation of discarding the charges of the photoelectric transducers and newly starting exposure (starting accumulation charges).

A signal read out by readout operation due to the readout scanning system corresponds to the amount of light having been incident after the immediately preceding readout operation or electronic shutter operation. Then, a time period from readout timing or sweep timing due to the immediately preceding readout operation or electronic shutter operation to readout timing due to the current readout operation is an accumulation time (exposure time) of the charge in the unit pixel.

Signals outputted from individual unit pixels in pixel row having undergone selective scanning due to the vertical drive section 112 are supplied to the column processing section 113 through the respective vertical signal lines 117. The column processing section 113 performs predetermined signal processing on the signals outputted from the individual unit pixels in selected row through the vertical signal line 117 for the respective pixel columns of the pixel array section 111, and in addition, temporarily holds the pixel signals after the signal processing.

Specifically, the column processing section 113 performs at least noise removing processing, for example, CDS (Correlated Double Sampling) processing as the signal processing. By this CDS processing due to the column processing section 113, fixed pattern noises intrinsic to pixels such as reset noise and scattering of thresholds of amplification transistors is removed. The column processing section 113 can be provided not only with the function of the noise removing processing but, for example, with an AD (Analog Digital) conversion function, so as to output signal levels in digital signals.

The horizontal drive section 114 is configured of a shift register, an address decoder and the like, and sequentially selects unit circuits corresponding to individual pixel columns in the column processing section 113. By selective scanning due to this horizontal drive section 114, the pixel signals having undergone the signal processing in the column processing section 113 are sequentially outputted.

The system control section 115 is configured of a timing generator generating various timing signals, and the like, and performs drive controls on the vertical drive section 112, column processing section 113, horizontal drive section 114 and the like based on the various timing signals generated by the relevant timing generator.

The signal processing section 118 has at least an addition processing function, and performs various kinds of signal processing such as the addition processing on the pixel signals outputted from the column processing section 113. The data storage section 119 temporarily stores data used for such processing as the signal processing in the signal processing section 118.

[Unit Pixel Configuration]

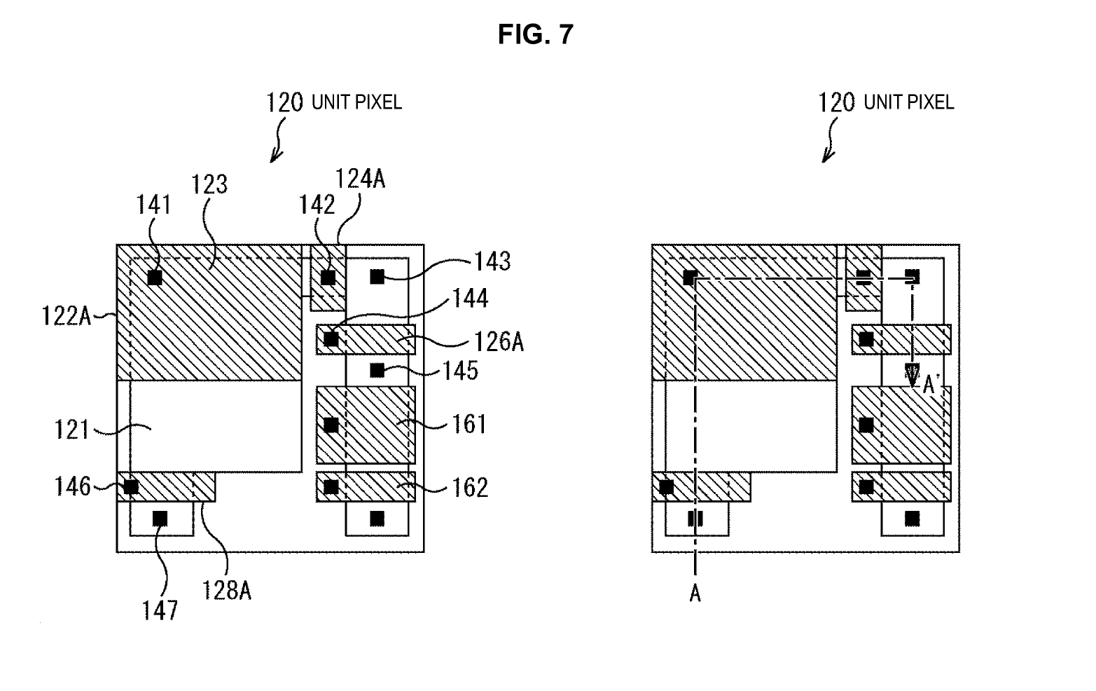

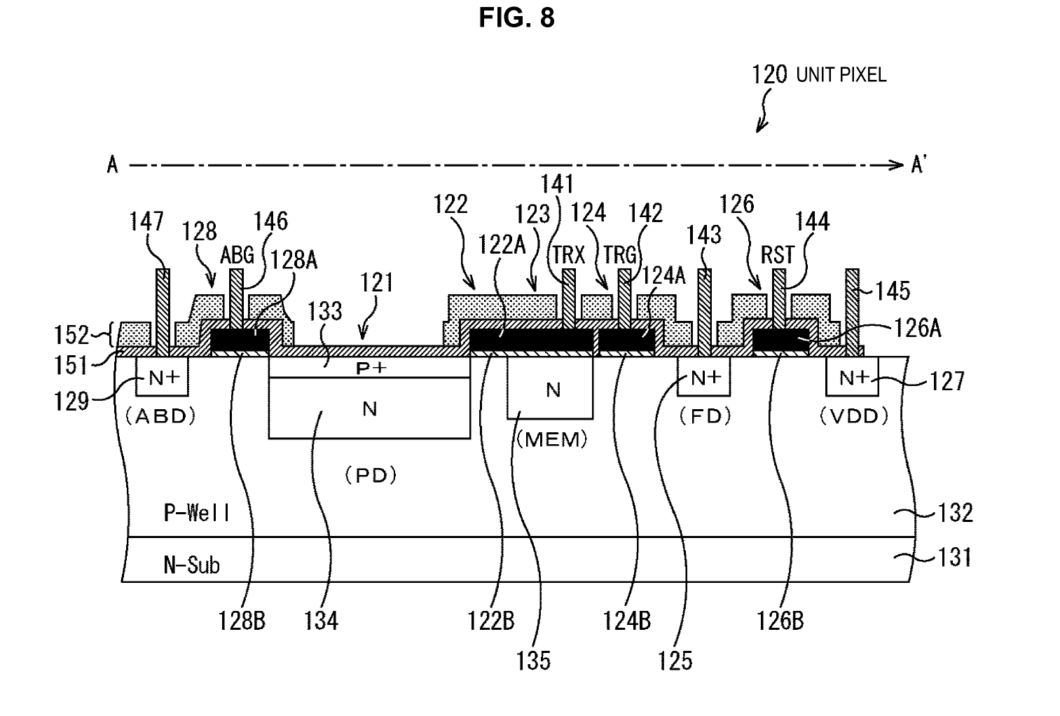

Next, a specific configuration of each of unit pixels 120 arranged in the matrix form in the pixel array section 111 in FIG. 6 will be described with reference to FIGS. 7 and 8. FIG. 7 illustrates plan diagrams of the configuration of the unit pixel 120. FIG. 8 illustrates a configuration example of a cross section of the unit pixel 120 taken in an A-A′ direction illustrated in the plan diagram on the right side of FIG. 7.

The unit pixel 120 includes, as the photoelectric transducer, a photodiode (PD) 121, for example. The photo diode 121 is a buried photodiode formed, for example, by forming a P-type layer 133, on the substrate-front-surface side, in a P-type well layer 132 formed on an N-type substrate 131 and by burying an N-type buried layer 134 in the P-type well layer 132. Note that the P-type layer 133 and the N-type buried layer 134 each have an impurity density causing a depletion state at the time of discharging a charge therefrom.

The unit pixel 120 includes a first transfer gate (TRX) 122, a memory part (MEM) 123, a second transfer gate (TRG) 124, and a floating diffusion (FD) 125, in addition to the photo diode 121.

The first transfer gate 122 includes: a gate electrode 122A formed by a polycrystalline semiconductor; and a gate insulating film 122B. The gate electrode 122A is formed in such a manner as to cover a portion between the photo diode 121 and the memory part 123 and part or all of an upper portion of the memory part 123 with the gate insulating film 122B placed in between. A contact 141 for wiring is connected to an upper portion of the gate electrode 122A on the memory part 123 side. When a transfer pulse TRX is applied to the gate electrode 122A through the contact 141, the first transfer gate 122 transfers a charge accumulated in the photo diode 121.

The memory part 123 is formed by an N-type buried channel 135 formed below the gate electrode 122A and having an impurity density causing a depletion state at the time of discharging the charge therefrom, and accumulates therein the charge transferred by the first transfer gate 122 from the photo diode 121. Note that since the memory part 123 is formed by the buried channel 135, it is possible to prevent a dark current from occurring at a Si—SiO2 interface and contribute to image quality enhancement.

In addition, it is possible to perform modulation on the memory part 123 by arranging the gate electrode 122A in the upper portion of the memory part 123 and by applying the transfer pulse TRX to the gate electrode 122A. In other words, applying the transfer pulse TRX to the gate electrode 122A leads to a deep potential of the memory part 123. This leads to a larger saturation amount of the charge in the memory part 123 than that in the case without modulation.

The second transfer gate 124 includes: a gate electrode 124A formed by a polycrystalline semiconductor; and a gate insulating film 124B. The gate electrode 124A is formed on a portion between the memory part 123 and the floating diffusion 125 with the gate insulating film 124B placed in between. A contact 142 for wiring is connected to an upper portion of the gate electrode 124A. When a transfer pulse TRG is applied to the gate electrode 124A through the contact 142, the second transfer gate 124 transfers the charge accumulated in the memory part 123.

The floating diffusion 125 is a charge voltage transducer formed by an N-type layer having an impurity density enabling electrical connection of a contact 143 for wiring and converts the charge transferred by the second transfer gate 124 from the memory part 123. The contact 143 for wiring is connected to an upper portion of the floating diffusion 125.

A reset gate 126 includes: a gate electrode 126A formed by a polycrystalline semiconductor; and a gate insulating film 126B. The gate electrode 126A is formed above a portion between the floating diffusion 125 and a charge discharging part (VDD) 127 with the gate insulating film 126B placed in between. A contact 144 for wiring is connected to an upper portion of the gate electrode 126A. When a reset pulse RST is applied to the gate electrode 126A through the contact 144, the reset gate 126 thereby transfers the charge from the floating diffusion 125 to the charge discharging part 127, so that the floating diffusion 125 is reset.

Note that since the contact 141 of the first transfer gate 122 and the contact 144 of the reset gate 126 are connected to the vertical drive section 112 through one of the pixel drive lines 116 which is shared by the contacts 141 and 144, the transfer pulse TRX applied to the gate electrode 122A and the reset pulse RST applied to the gate electrode 126A have the same potential. The details will be described later.

The unit pixel 120 further includes an amplifier circuit 161 and a selection circuit 162. The amplifier circuit 161 is connected to the floating diffusion 125. When the selection circuit 162 selects the unit pixel 120 as a target for reading out a pixel signal, the amplifier circuit 161 reads out a pixel signal indicating a voltage of the floating diffusion 125 and supplies the column processing section 113 with the voltage through the corresponding vertical signal line 117.

The unit pixel 120 further includes a charge discharging gate (ABG) 128 and a charge discharging part (ABD) 129. When a control pulse ABG is applied to a gate electrode 128A through a contact 146 for wiring, the charge discharging gate 128 transfers the charge accumulated in the photo diode 121. In other words, the charge is transferred by the charge discharging gate 128 from the photo diode 121 to the charge discharging part 129 and then discharged.

A contact 147 for wiring is connected to an upper portion of the charge discharging part 129. The charge discharging gate 128 and the charge discharging part 129 exert an effect of preventing the charge in the photo diode 121 from overflowing therefrom due to saturation of the photo diode 121 during the readout time period after the end of the exposure.

Note that an insulating film 151 having a three-layer structure of, for example, an oxide film, a nitride film, and an oxide film is formed on an upper surface of the unit pixel 120. The insulating film 151 also functions as a film optically preventing reflection. The insulating film 151 has openings corresponding to only portions where the contacts 141 to 147 are formed. Note that the layers forming the insulating film 151 each have an optimum film pressure set in consideration of a withstand pressure and optical sensitivity characteristics.

Further, a light shielding film 152 made of metal such as tungsten is formed on an upper surface of the insulating film 151. As illustrated in FIG. 8, the light shielding film 152 has openings corresponding to only portions where a light receiving portion of the photo diode 121 and the contacts 141 to 147 are formed.

One of the opening portions of the light shielding film 152 corresponding to the light-receiving portion of the photo diode 121 is set in optimum size and location based on trade-off between the optical sensitivity of the photo diode 121 and noise generated in the memory part 123. Note that the noise generated in the memory part 123 is noise generated according to the same principle as in a smear in a CCD (Charge Coupled Device) image sensor. For example, the noise is generated because a charge is generated in the memory part 123 when light enters the memory part 123 or a vicinity thereof from an opening of the light shielding film 152 or because charges generated outside are diffused to flow in the memory part 123.

The other openings of the light shielding film 152 corresponding to the contacts 141 to 147 are formed to be slightly larger than cross sections of the respective contacts 141 to 147 so that a short-circuit between each of the contacts 141 to 147 and the light shielding film 152 can be prevented. Accordingly, a predetermined space is secured therebetween. However, a too small space therebetween is likely to cause a short-circuit. On the other hand, a too large space therebetween causes light to stray into the corresponding opening portion, and the stray light increases noise according to the same principle as in the aforementioned smear. Accordingly, the opening portions corresponding to the contacts 141 to 147 are each also set in an optimum size based on the tradeoff between the two characteristics.

[Method for Driving Unit Pixels]

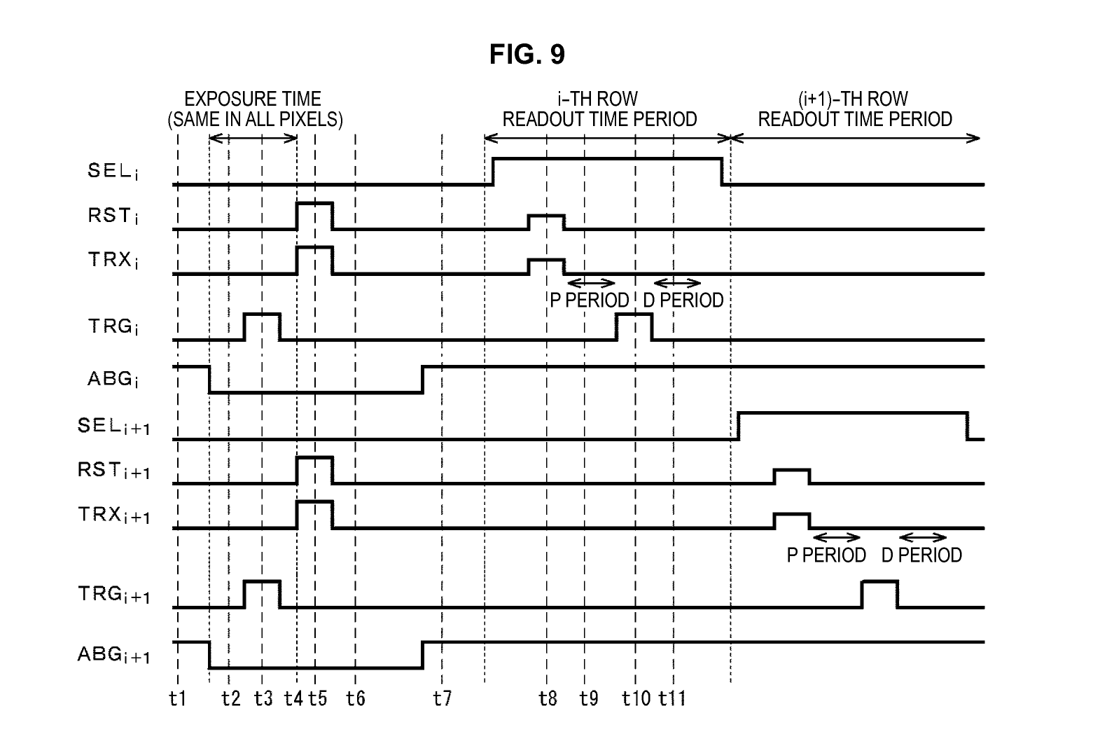

Next, a method for driving the unit pixels 120 will be described with reference to FIGS. 9 to 21.

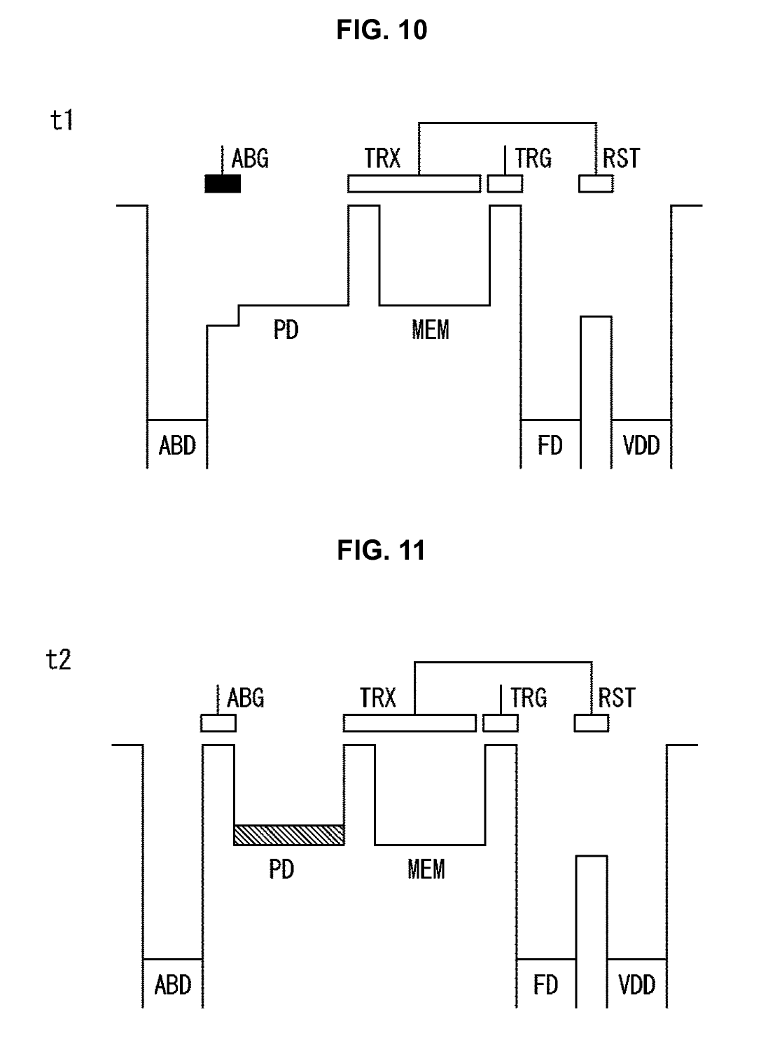

Note that FIG. 9 illustrates a timing chart of a selection pulse SEL, a reset pulse RST, a transfer pulse TRX, a transfer pulse TRG, and a control pulse ABG, in a one-frame time period, of each of unit pixels 120 in the i-th and (i+1)-th rows in the pixel array section 111. FIGS. 10 to 21 illustrate potential diagrams of the unit pixel 120 in the A-A′ direction in FIG. 8 at times t1 to t11 in FIG. 9, and the description is given with reference to the figures as appropriate.

In each potential diagram, a potential is indicated in the vertical direction. In the upward direction, the potential becomes lower and a barrier becomes higher. On the other hand, in a downward direction, the potential becomes higher and the barrier becomes lower. Further, squares shown below characters of ABG, TRX, TRG, and RST indicate the gate electrodes for the control pulse ABG, the transfer pulse TRX, the transfer pulse TRG, and the reset pulse RST and states thereof. Specifically, a gate electrode shown by a black square indicates that the corresponding pulse is on, and a gate electrode shown by an outlined square indicates that the pulse is off.

Hereinafter, when the control pulse ABG, the transfer pulse TRX, the transfer pulse TRG, or the reset pulse RST is on, a voltage of the pulse is referred to as an ON voltage. When the pulse is off, a voltage thereof is referred to as an OFF voltage.

Firstly, when the control pulse ABG is turned on at time t1, the photo diode 121 is depleted, that is, becomes in a state of being kept reset. As the result, light enters the photo diode 121, but a charge obtained by photoelectrically converted is typically discharged to the charge discharging part (ABD) 129 (FIG. 10).

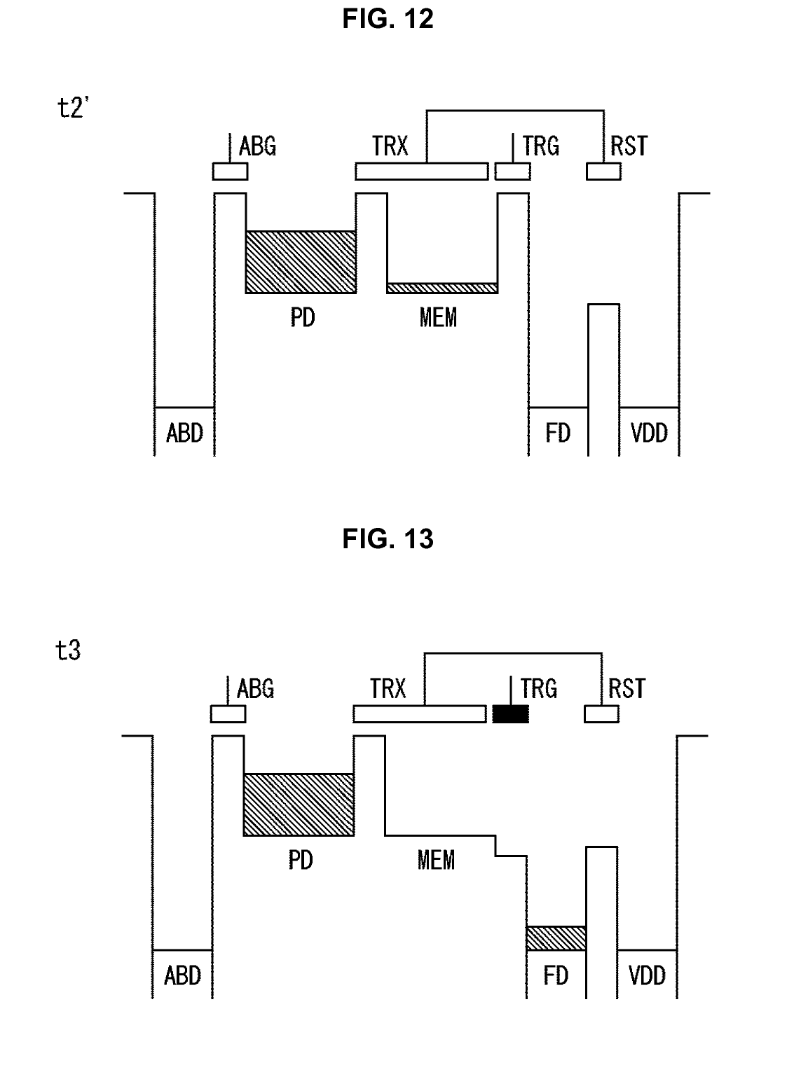

Next, when the control pulse ABG is turned off, charges obtained by photoelectrically converting incident light are started to be accumulated in the photo diode 121 of each pixel simultaneously. In other words, when the control pulse ABG is switched from on to off, a charge corresponding to an amount of incident light is accumulated, and exposure is started simultaneously in each pixel. Then, upon start of the exposure, the charge is accumulated in the photo diode 121 in accordance with elapsed time (time t2 in FIG. 11). When the charge is accumulated in the photo diode 121, noise components such as a smear and a dark current are accumulated also in the memory part 123 simultaneously (time t2′ in FIG. 12).

For this reason, before the charge accumulated in the photo diode 121 is then transferred to the memory part 123, the transfer pulse TRG is turned on for resetting the noise components accumulated in the memory part 123. Thereby, the noise components accumulated in the memory part 123 are transferred to the floating diffusion 125 (time t3 in FIG. 13). Upon completion of the transfer of the noise components, the transfer pulse TRG is turned off. Since the reset pulse RST is kept off at this time, the noise components are only transferred from the memory part 123 to the floating diffusion 125.

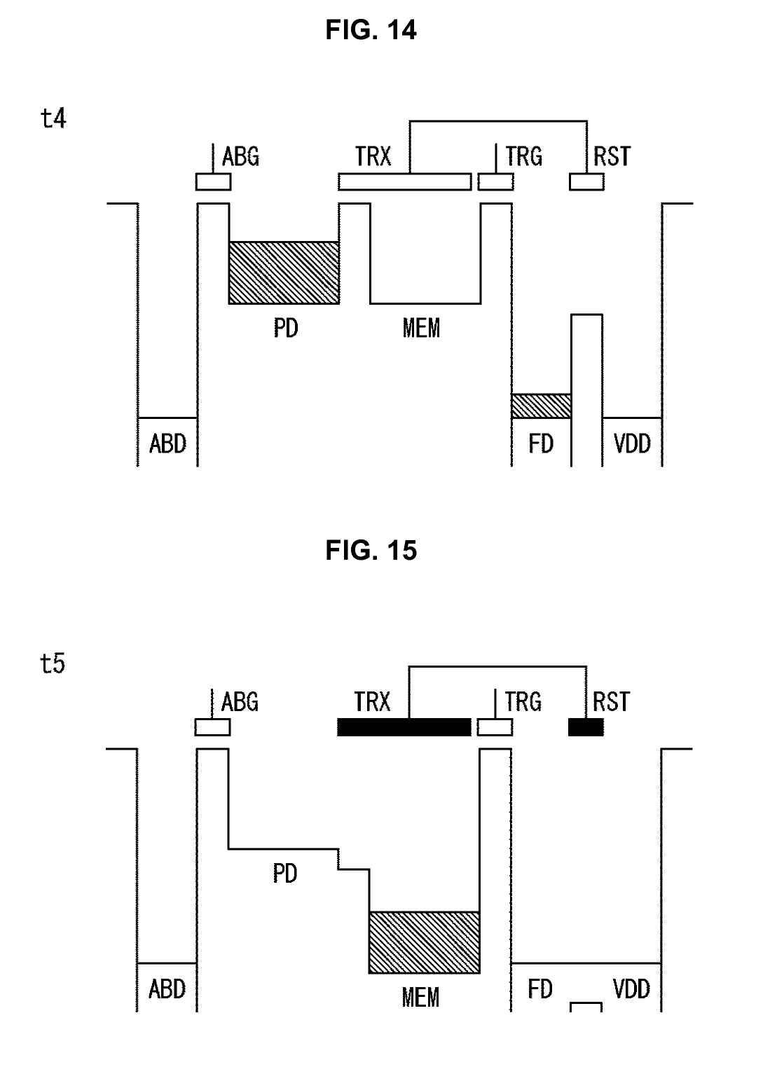

At time t4, the exposure is terminated simultaneously in each pixel, and a charge accumulation time period ends (FIG. 14). In addition, since the memory part 123 is reset, the transfer pulse TRX is turned on, and the charge accumulated in the photo diode 121 is transferred to the memory part 123 simultaneously in each pixel (time t5 in FIG. 15). At this time, the reset pulse RST transmitted through a drive line shared with the transfer pulse TRX is simultaneously turned on, and further the reset pulse RST has the same potential as that of the transfer pulse TRX. Accordingly, the floating diffusion 125 also becomes in the reset state simultaneously (time t5 in FIG. 15).

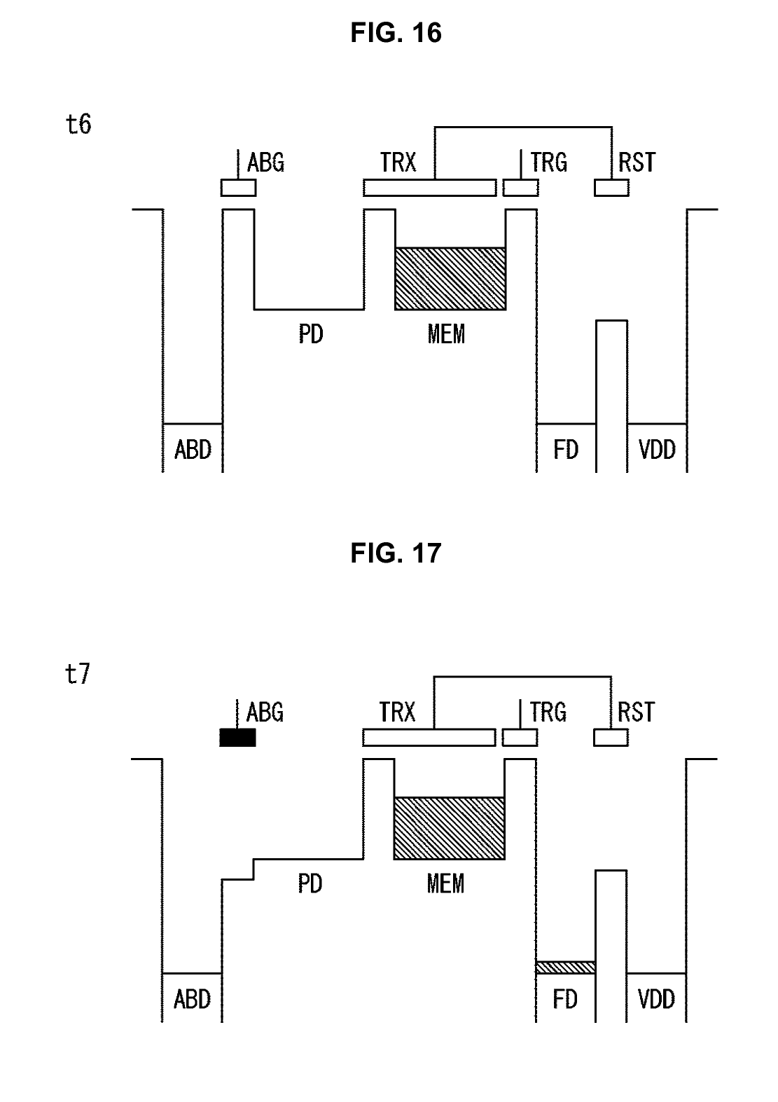

Next, when both the transfer pulse TRX and the reset pulse RST are turned off, the charge transferred from the photo diode 121 is accumulated in the memory part 123 (time t6 in FIG. 16).

Thereafter, the control pulse ABG is turned on, so that the photo diode 121 is reset (time t7 in FIG. 17). This can prevent the charge generated in the photo diode 121 from flowing into the memory part 123 (exudation). Consequently, it is possible to prevent destruction of the held signal.

After the accumulation time period ends, a readout time period starts in which pixel signals are read out based on charges accumulated in the respective pixels 120. The pixel signals are read out in units of a pixel or a plurality of pixels. For example, when a pixel signal of the unit pixel 120 in the i-th row is read out, a selection pulse SEL corresponding to the selection circuit 162 for the i-th row is turned on to select the unit pixel 120 in the i-th row as a target for reading the pixel signal.

Hereinafter, an example is shown in which a charge accumulated in the memory part 123 is transferred to the floating diffusion 125 in row unit and then is outputted. In this case, it is necessary to reset the floating diffusion 125 before transferring the charge from the memory part 123 to the floating diffusion 125. When the reset pulse RST is turned on at this time, the transfer pulse TRX sharing a drive line with the reset pulse RST is also turned on, and thus a concern arises that the charge might flow out from the memory part 123 to the photo diode 121. Hence, in the unit pixel 120, the gate electrode 124A of the second transfer gate 124 is formed in such a manner as to partially or entirely cover the upper portion of the memory part 123. Thereby, application of the transfer pulse TRX leads to a deep potential of the memory part 123. Even if the transfer pulse TRX is turned on, the charge does not flow back from the memory part 123.

Meanwhile, an ON voltage to be applied at this time as the reset pulse RST and the transfer pulse TRX is preferably lower than an ON voltage applied at the time of transferring the charge from the photo diode 121 to the memory part 123 at time t5 (hereinafter, the voltage is referred to as an intermediate voltage). Specifically, for example, when an ON voltage applied at time t5 is 3V, an intermediate voltage of 2V is applied as an ON voltage to be applied at time t8.

In other words, the intermediate voltage is such a voltage that causes a state where the floating diffusion 125 can be completely reset due to the reset pulse RST and a charge is prevented from being transferred between the photo diode 121 and the memory part 123 due to the transfer pulse TRX.

Note that there is another method by which a charge held in the memory part 123 is prevented from being destroyed by applying a voltage equivalent to the ON voltage applied at time t5, instead of the intermediate voltage. In other words, the potentials may be designed so that a charge generated in the photo diode 121 can flow into only the charge discharging part (ABD) 129 even if the transfer pulse TRX is turned on when the control pulse ABG is turned on. However, even if the method is employed, it is difficult to fully prevent the charge from flowing into the memory part 123 in the case where a large amount of light enters and thus a large amount of charge is generated. Thus, it is preferable to employ the method using the intermediate voltage.

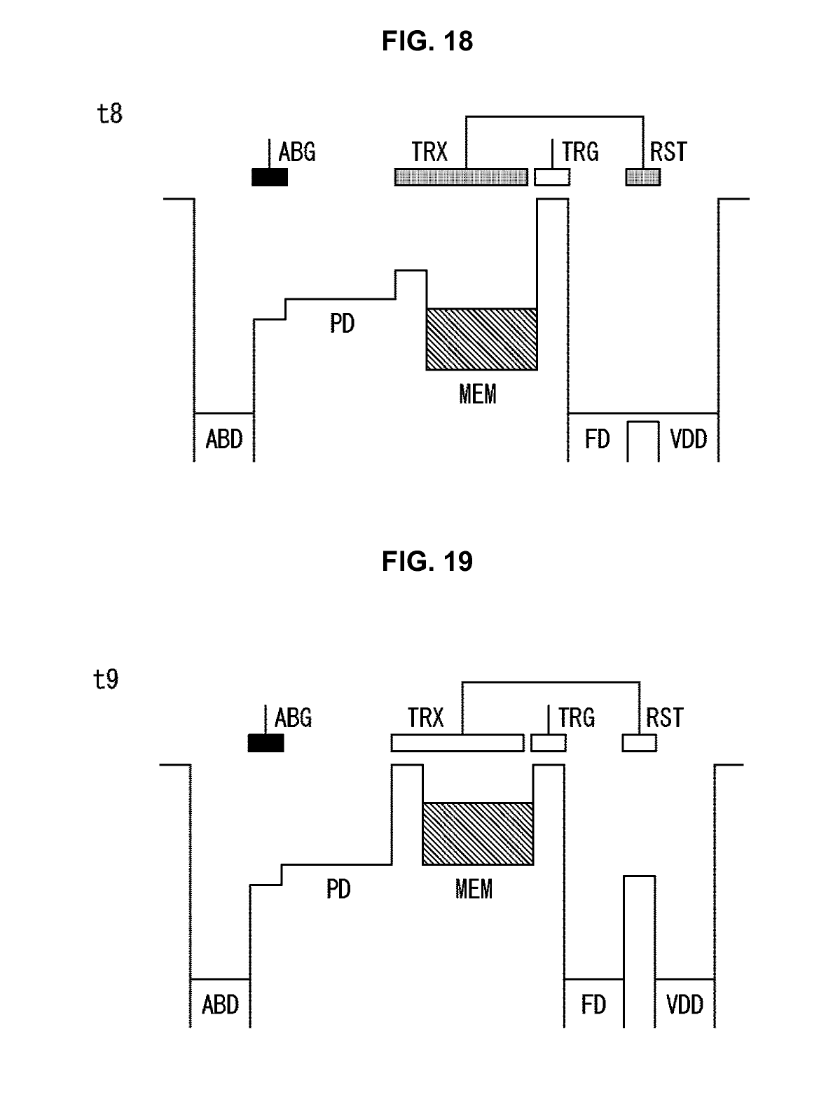

As described above, it is possible to reset the floating diffusion 125 without destroying the charge held in the memory part 123 (time t8 in FIG. 18). After the floating diffusion 125 is reset, the transfer pulse TRX and the reset pulse RST are turned off. Then, a P phase (signal indicating the reset level) in CDS is read out in a P period (time t9 in FIG. 19).

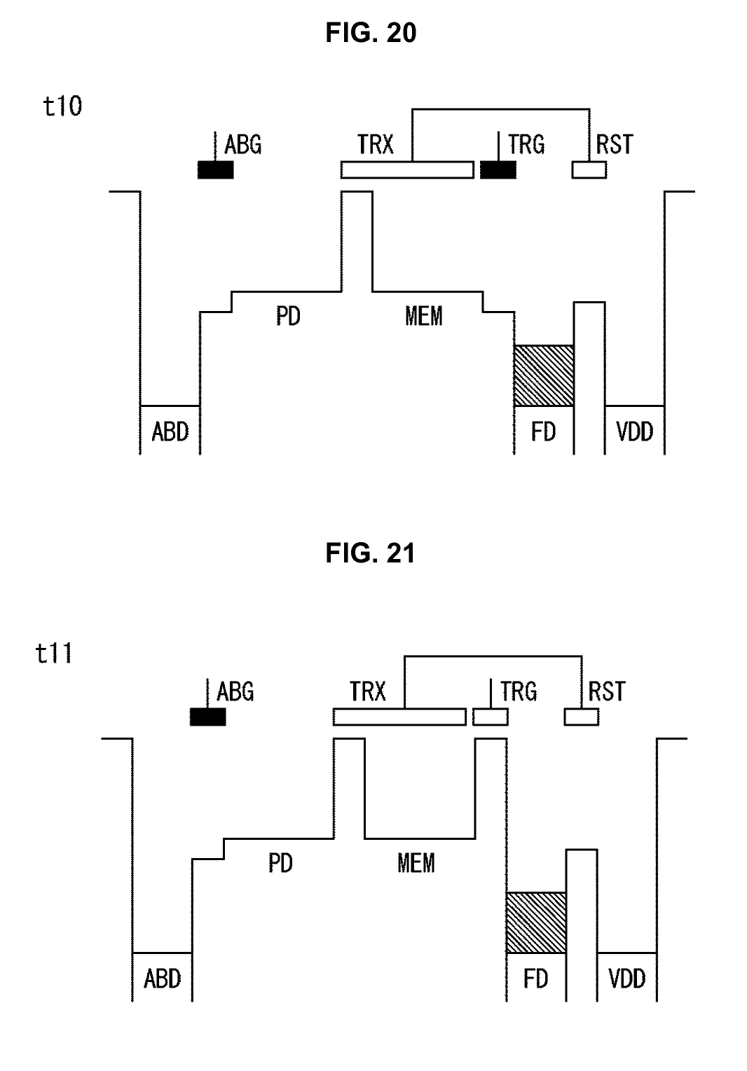

Subsequently, the transfer pulse TRG is turned on, the charge accumulated in the memory part 123, that is, the charge accumulated in the photo diode 121 in the accumulation time period and then transferred to the memory part 123 is transferred to the floating diffusion 125 (time t10 in FIG. 20). Then, after the transfer pulse TRG is turned off, a pixel signal indicating the signal level based on the charge transferred to the floating diffusion 125 is read out in a D period (time t11 in FIG. 21).

Thereafter, the selection pulse SEL is turned off, the readout time period of the unit pixels 120 in the i-th row ends, and transition to a readout time period of the unit pixels 120 in the (i+1)-th row takes place. Then, after readout of pixel signals in all the rows is completed, transition to the beginning of the timing chart in FIG. 9 takes place as necessary to start an accumulation time period of the next frame.

As described above, in the unit pixels 120 each having a pixel structure having a memory part, a drive line for transmitting a transfer pulse TRX and a reset pulse RST is shared to reduce the number of drive lines. Thereby, it is possible to output a signal without kTC noise. In other words, even in the case where the same drive line is used for the transfer pulse TRX and the reset pulse RST, it is possible to achieve both the operations of transferring a charge from the photo diode 121 to the memory part 123 and resetting the floating diffusion 125, for example, by applying an intermediate voltage in resetting the floating diffusion 125.

In the aforementioned description, the first transfer gate 122 is formed in such a manner as to partially or entirely cover the upper portion of the memory part 123. It is preferable to employ a structure like that of a register of a CCD, for example, in which the first transfer gate 122 covers at least part of the memory part 123.

In addition, the structure of the unit pixel 120 is not limited to the structure in FIG. 8, and another structure may be employed. For example, a structure may also be employed in which a P-type layer is formed in the memory part 123 on the substrate-front-surface side as in the photo diode 121, and in which a transfer gate is provided between the photo diode 121 and the memory part 123. When a driving method illustrated in FIG. 9 is employed using this structure, even application of the intermediate voltage as the reset pulse RST and the transfer pulse TRX at time t8 (FIG. 18) does not result in a deep potential of the memory part 123 which would be obtained in conjunction with the transfer pulse TRX. For this reason, the charge held in the memory part 123 flows back to the photo diode 121 side. Accordingly, when the intermediate voltage is used in driving the pulses in FIG. 9 in this structure, an amount of the charge which can be held in the memory part 123 (a saturation amount of a charge in the memory part 123) is an amount of charge determined based on the state of the intermediate voltage.

As described above, sharing a transfer pulse TRX and a reset pulse RST in a pixel used for implementing the global exposure makes it possible to reduce the number of drive lines. As the result, the area of openings guiding incident light into a photo diode can be increased, and thus the sensitivity can be enhanced. Moreover, reducing the number of drive lines can reduce a risk of lowering a yield, such as a wiring short-circuit.

[Modification of Solid-State Imaging Apparatus Configuration]

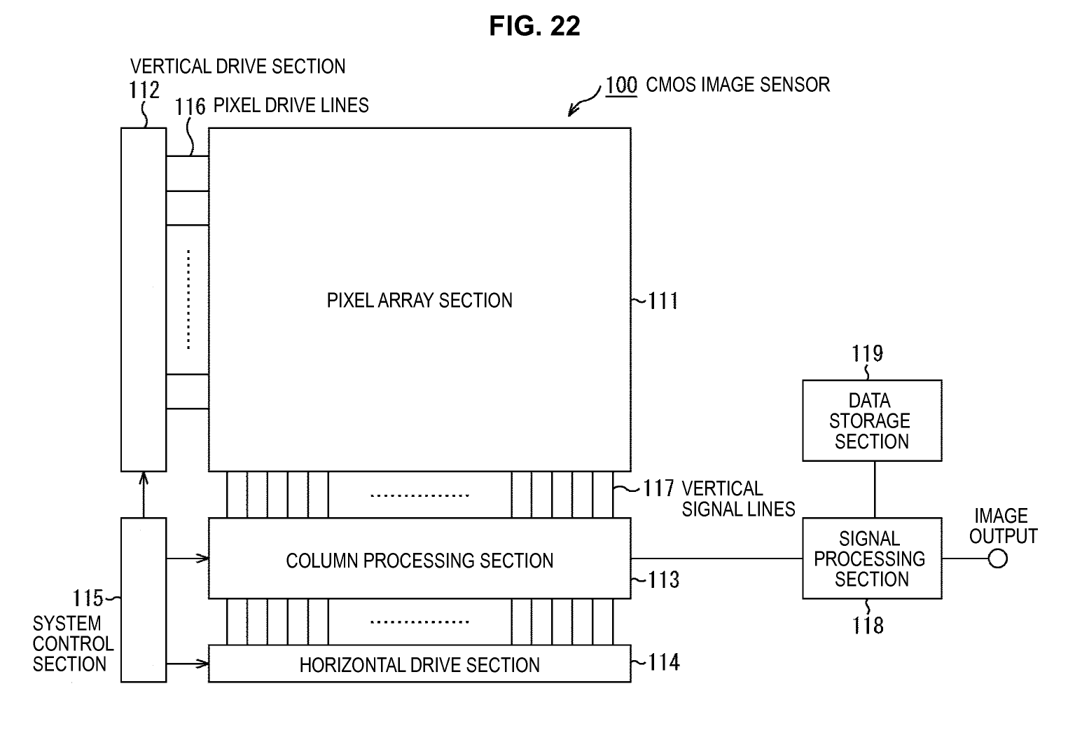

In the aforementioned description, the configuration is employed in which the data storage section 119 is provided in parallel with the signal processing section 118 in the subsequent stage of the column processing section 113, as illustrated in FIG. 6, but is not limited to this. For example, as illustrated in FIG. 22, another configuration may be employed in which the data storage section 119 is provided in parallel with the column processing section 113. With the configuration, the horizontal drive section 114 simultaneously reads out data by horizontal scanning, and the signal processing section 118 in the subsequent stage executes signal processing on the data.

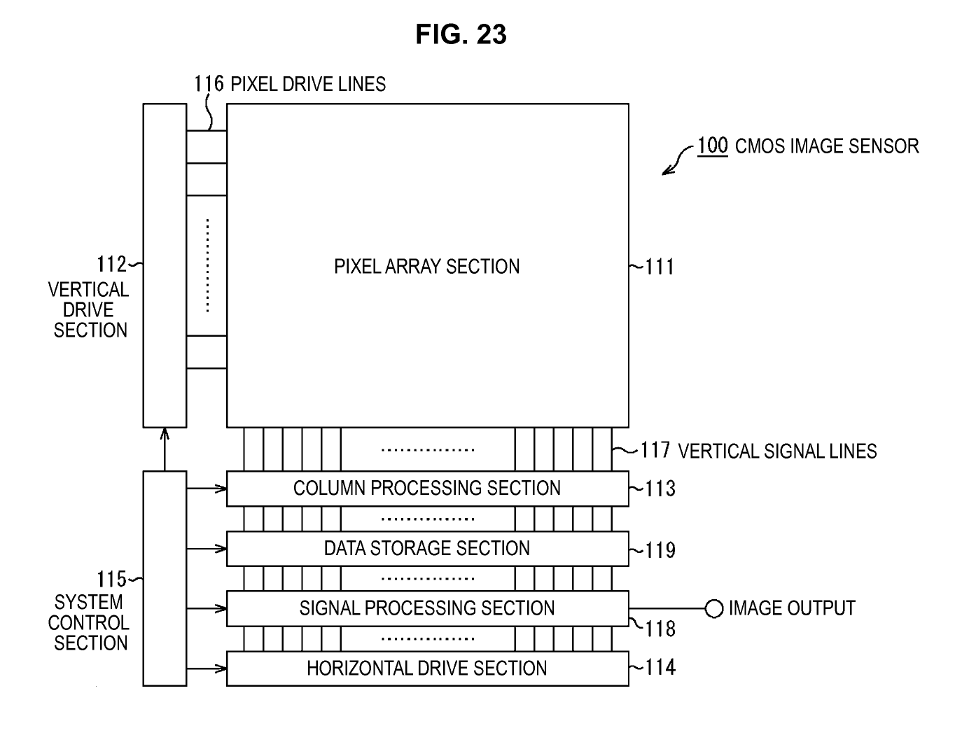

Further, as illustrated in FIG. 23, still another configuration may be employed in which the column processing section 113 is provided with an AD conversion function of performing AD conversion for each column or each column group of the pixel array section 111, and in which the data storage section 119 and the signal processing section 118 are provided in parallel with the column processing section 113. With the configuration, the signal processing section 118 performs signal removing processing in an analog or digital manner, and thereafter the data storage section 119 and the signal processing section 118 execute processing thereof for each column or each column group.

Note that application of the present technology is not limited to the application to the solid-state image sensor. That is, the present technology is applicable to a general electronic device using a solid-state image sensor for an image capturing section (a photoelectric conversion section), the general electronic device including an imaging apparatus such as a digital still camera or a video camera, a mobile terminal device having an image capturing function, a copier using a solid-state image sensor for an image reading section, and the like. The solid-state image sensor may be formed as one chip or may be formed as a module having an image capturing function in which an image capturing section and either a signal processing section or an optical system are packaged together.

[Configuration Example of Electronic Device to which Present Technology is Applied]

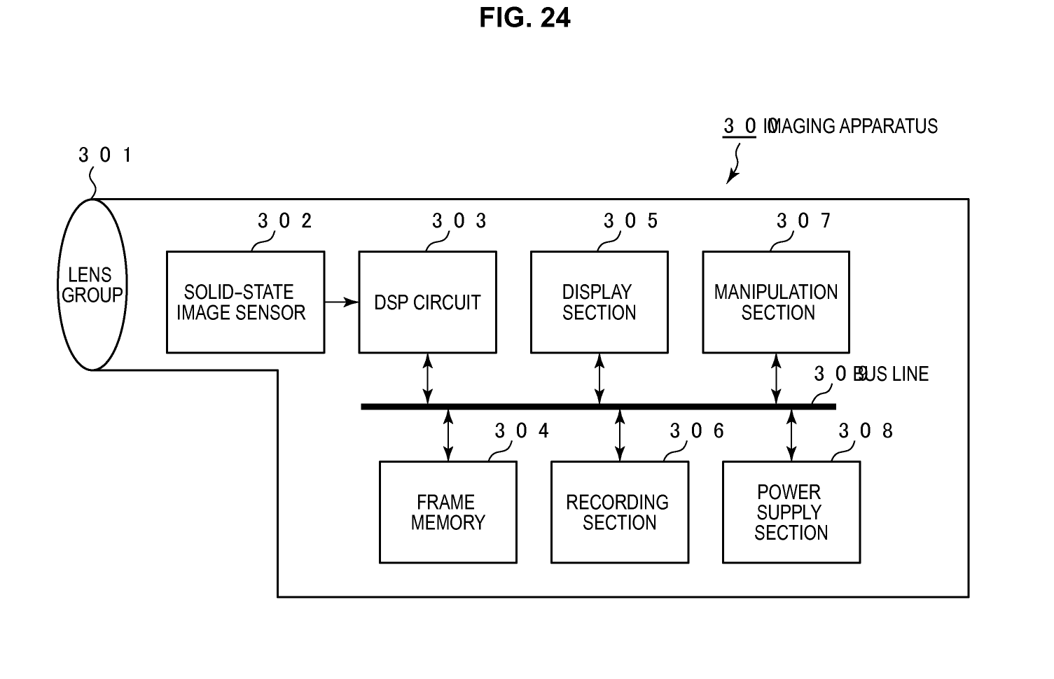

FIG. 24 is a block diagram of a configuration example of an imaging apparatus serving as an electronic device to which the present technology is applied.

An imaging apparatus 300 in FIG. 24 includes: a lens group 301 formed by a lens group or the like; a solid-state image sensor (an image-capturing device) 302 employing the aforementioned configuration of the unit pixels 120, and a DSP (Digital Signal Processor) circuit 303 which is a camera signal processing circuit. The imaging apparatus 300 also includes a frame memory 304, a display section 305, a recording section 306, a manipulation section 307, and a power supply section 308. The DSP circuit 303, the frame memory 304, the display section 305, the recording section 306, the manipulation section 307, and the power supply section 308 are connected to each other via a bus line 309.

The optical section 301 takes in incident light (image light) from a subject to form an image on an imaging surface of the solid-state image sensor 302. The solid-state image sensor 302 converts a light amount of incident light into an electrical signal on a pixel basis and outputs the electrical signal, the incident light being used for forming the image on the imaging surface by the optical section 301. It is possible to use, as the solid-state image sensor 302, a solid-state image sensor such as the CMOS image sensor 100 according to the aforementioned embodiment which is arranged on the CMOS image sensor, that is, a solid-state image sensor which makes it possible to capture an image without distortion by using global exposure.

The display section 305 includes a panel display device such as a liquid crystal panel or an organic EL (Electro Luminescence) panel, and displays a moving image or a still image captured by the solid-state image sensor 302. The recording section 306 records the moving image or the still image captured by the solid-state image sensor 302 in a recording medium such as a video tape or a DVD (Digital Versatile Disk).

The manipulation section 307 issues manipulation instructions for various functions of the imaging apparatus 300 in accordance with user's manipulation. The power supply section 308 appropriately supplies the DSP circuit 303, the frame memory 304, the display section 305, the recording section 306, and the manipulation section 307 with power to cause these sections to operate.

As described above, the use of the CMOS image sensor 100 according to the aforementioned embodiment as the solid-state image sensor 302 makes it possible to perform processing of reducing noise including even kTC noise and thus to secure high S/N. Accordingly, it is possible to achieve high quality of a captured image in the imaging apparatus 300 such as a video camera, a digital still camera, or further a camera module for a mobile device such as a mobile phone.

In addition, the aforementioned embodiment has been described by taking as an example the case where the present technology is applied to the CMOS image sensor including the unit pixels arranged in a matrix form, the unit pixels each sensing, as a physical quantity, a signal charge corresponding to a light amount of visible light. The application of the present technology, however, is not limited to the application to the CMOS image sensor. The present technology is applicable to a general column-system solid-state image sensor including a column processing section arranged for each pixel column in a pixel array section.

The application of the present technology is not limited to the application to the solid-state image sensor which captures an image by sensing distribution of incident light amounts of visible light. The present technology is also applicable to: a solid-state image sensor which captures an image based on distribution of incidence amounts of infrared rays, X-rays, particles or the like; and a general solid-state image sensor in a broad sense (a physical-quantity distribution sensing device) such as a fingerprint detection sensor which captures an image by sensing distribution of other physical quantities such as pressures or electrostatic capacitances.

Also, in the present specification, the steps described in a flowchart may be naturally executed in time series along the described order, or, when they are not processed in the time series, they may be executed in parallel or at a requested timing such as call timing.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1) A solid-state image sensor including:

a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region,

wherein the first transfer gate and the reset section are connected to an identical drive section through a drive line shared by the first transfer gate and the reset section, and are simultaneously driven by the drive section.

(2) The solid-state image sensor according to (1),

wherein the first transfer gate partially or entirely covers the charge holding region.

(3) The solid-state image sensor according to (1) or (2),

wherein the drive section sets a first voltage in driving the reset section to be lower than a second voltage in driving the first transfer gate.

(4) A method for controlling a solid-state image sensor, the solid-state image sensor including

a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region; and

a drive section which drives the plurality of unit pixels,

wherein the drive section simultaneously drives the first transfer gate and the reset section, the drive section being connected to the first transfer gate and the reset section through a drive line shared by the first transfer gate and the reset section.

(5) An electronic device having a solid-state image sensor mounted thereon, the solid-state image sensor including

a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region,

wherein the first transfer gate and the reset section are connected to an identical drive section through a drive line shared by the first transfer gate and the reset section, and are simultaneously driven by the drive section.

The present disclosure contains subject matter related to that disclosed in Japanese Priority Patent Application JP 2012-128539 filed in the Japan Patent Office on Jun. 6, 2012, the entire content of which is hereby incorporated by reference.

What is claimed is:

1. A solid-state image sensor comprising:
a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region,
wherein the first transfer gate and the reset section are connected to an identical drive section through a drive line shared by the first transfer gate and the reset section, and are simultaneously driven by the drive section.

2. The solid-state image sensor according to claim 1,
wherein the first transfer gate partially or entirely covers the charge holding region.

3. The solid-state image sensor according to claim 1,
wherein the drive section sets a first voltage in driving the reset section to be lower than a second voltage in driving the first transfer gate.

4. A method for controlling a solid-state image sensor, the solid-state image sensor including
a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region; and
a drive section which drives the plurality of unit pixels,
wherein the drive section simultaneously drives the first transfer gate and the reset section, the drive section being connected to the first transfer gate and the reset section through a drive line shared by the first transfer gate and the reset section.

5. An electronic device having a solid-state image sensor mounted thereon, the solid-state image sensor including
a plurality of unit pixels each including
a photoelectric transducer which generates a charge corresponding to an amount of incident light and accumulates the charge therein,
a first transfer gate which transfers the charge accumulated in the photoelectric transducer,
a charge holding region in which the charge transferred from the photoelectric transducer by the first transfer gate is held,
a second transfer gate which transfers the charge held in the charge holding region,
a floating diffusion region in which the charge transferred from the charge holding region by the second transfer gate is held to be read out as a signal, and
a reset section which resets the charge in the floating diffusion region,
wherein the first transfer gate and the reset section are connected to an identical drive section through a drive line shared by the first transfer gate and the reset section, and are simultaneously driven by the drive section.
